(19) United States
(12) Patent Application Publication
(10) Pub. No.: US 2018/0223444 A1
(43) Pub. Date: Aug. 9, 2018

(54) PLATING APPARATUS AND SUBSTRATE HOLDER USED TOGETHER WITH PLATING APPARATUS

(71) Applicant: EBARA CORPORATION, Tokyo (JP)

(72) Inventors: Toshio YOKOYAMA, Tokyo (JP); Tomonori HIRAO, Tokyo (JP); Sho TAMURA, Tokyo (JP)

(21) Appl. No.: 15/868,673

(22) Filed: Jan. 11, 2018

(30) Foreign Application Priority Data
Feb. 8, 2017 (JP) 2017-021309

(51) Int. Cl. C25D 17/00; C25D 17/06; C25D 5/10; C25D 5/02; H01L 21/288

(52) U.S. Cl. CPC C25D 17/004; C25D 17/06; H01L 21/2885; C25D 5/028; C25D 5/10

(57) ABSTRACT

The present invention provides a plating apparatus capable of individually controlling a plating process on a front surface and a back surface of a substrate and a substrate holder usable for such a plating apparatus. A substrate holder for holding a substrate which is a plating target during a plating process is provided and such a substrate holder includes a body part for holding the substrate, provided with a first opening and a second opening, the body part is configured such that when the body part holds the substrate, a plated region on the front surface of the substrate is exposed through the first opening and a plated region on the back surface of the substrate is exposed through the second opening and a sealing part that protrudes from a peripheral portion is included in at least part of the peripheral portion of the body part.

### CROSS-REFERENCE TO RELATED APPLICATION

This application claims priority to Japanese Patent Application No. 2017-021309 filed Feb. 8, 2017, the entire contents of which are hereby incorporated by reference.

### TECHNICAL FIELD

The present invention relates to a plating apparatus and a substrate holder used together with the plating apparatus.

### BACKGROUND ART

A trend toward a high-density constitution and fine structure of semiconductors such as a trend to further advance micromachining of Si and a trend toward a three-dimensional structure has been accelerating in recent years. Conventionally, a technique of incorporating a semiconductor into a mounting substrate (organic substrate) has been proposed, and techniques such as SiP (system in package) and EPD (embedded passive devices) have been proposed, studied and commercialized. The speed of technological development of such a mounting technique is accelerating, and development of multilayer wiring technique for producing a multilayer substrate such as a three-dimensional LSI by laminating a plurality of wiring substrates one on another is being further underway in recent years. For example, formation of a memory laminated structure using wire bonding and a combined structure such as package on package are being proposed. Furthermore, in a TSV (through silicon via) technique, a technique of three-dimensional packaging into a substrate having a thickness of 50 μm to 100 μm is also further progressing.

Under these circumstances, by applying different plating processes to a via formed on the front surface side of a substrate and a via formed on the back surface side of the substrate respectively using a new plating method, if it is possible to form different films on the front surface and the back surface of the substrate, it is expected that a circuit having a new laminated structure can be formed.

### CITATION LIST

### Patent Literature

PTL 1: Japanese Patent Application Laid-Open No.2016-160521

PTL 2: Japanese Patent Application Laid-Open No.201.6-135923

PTL 3: Japanese Patent Application Laid-Open No.2016-98399

### SUMMARY OF INVENTION

### Technical Problem

It is an object of the present invention to provide a plating apparatus and a substrate holder usable for such a plating apparatus capable of individually controlling a plating process for a front surface and a back surface of a substrate.

### Solution to Problem

[Aspect 1]

According to aspect 1, a substrate holder for holding a substrate which is a plating target during a plating process is provided and such a substrate holder includes a body part for holding the substrate provided with a first opening and a second opening and the body part is configured such that when the body part holds the substrate, a plated region on a front surface of the substrate is exposed through the first opening and a plated region on a back surface of the substrate is exposed through the second opening and includes a sealing part that protrudes from a peripheral portion of the body part in at least a part of the peripheral portion. According to the substrate holder of aspect 1, the substrate holder holding the substrate can divide a plating tank into a plurality of regions and can separate a plating liquid used for a plating process on the front surface of the substrate from a plating liquid used for a plating process on the back surface. Therefore, it is possible to execute different types of control with respect to the plating liquid used for the plating process on the front surface of the substrate and the plating liquid used for the plating process on the back surface. As an example, it is possible to use plating liquids varying in concentration and temperature for the front surface and the back surface of the substrate.

[Aspect 2]

According to aspect 2, the substrate holder according to aspect 1 further includes a first power supply mechanism for supplying a current to the front surface of the substrate and a second power supply mechanism for supplying a current to the back surface of the substrate. According to aspect 2, it is possible to control currents for the front surface and the back surface of the substrate independently of each other.

[Aspect 3]

According to aspect 3, in the substrate holder according to aspect 1 or aspect 2, the sealing part includes a bag body configured to inflate by introducing a gas thereinto.

[Aspect 4]

According to aspect 4, in the substrate holder according to aspect 1 or 2, the sealing part includes a rotatable wedge member.

[Aspect 5]

According to aspect 5, in the substrate holder according to any one of aspects 1 to 3, the sealing part includes at least one elastic member selected from a group of (1) a coated elastic member containing polyparaxylylene such as parylene (registered trademark), (2) an elastic member containing polyvinylidene fluoride (PVDF), (3) an elastic member containing polytetrafluoroethylene (PTFE), (4) an elastic member containing a copolymer including at least one of polyvinylidene fluoride (PVDF) and polytetrafluoroethylene (PTFE), and (5) an elastic member made of two-liquid fluorine rubber-based sealing member.

[Aspect 6]

According to aspect 6, in the substrate holder according to any one of aspects 1 to 5, the sealing part is provided at a position corresponding to a holder holding section of a plating tank when the substrate holder is disposed in the plating tank.

[Aspect 7]

According to aspect 7, a plating apparatus is provided, the plating apparatus including a plating tank for containing a plating liquid and a substrate holder for holding a substrate which is a plating target, in which the substrate holder includes a body part for holding the substrate, the body part being provided with a first opening and a second opening, the body part is configured such that when the body part holds the substrate, a plated region on a front surface of the substrate is exposed through the first opening and a plated region on a back surface of the substrate is exposed through the second opening, the body part includes a sealing part protruding from a peripheral portion of the body part in at least part of the peripheral portion, the plating tank includes a holder holding section that receives the sealing part of the substrate holder and is configured such that the substrate and the substrate holder divide the plating tank into a first portion and a second portion when the sealing part is received by the holder holding section of the plating tank. According to the plating apparatus of aspect 7, the substrate holder that holds the substrate can divide the plating tank into a plurality of regions, and the plating liquid used for a plating process on the front surface of the substrate can be separated from the plating liquid used for a plating process on the back surface. Therefore, it is possible to execute different types of control on the plating liquid used for the plating process on the front surface of the substrate and the plating liquid used for the plating process on the back surface. For example, it is possible to use plating liquids varying in concentration and temperature between the front surface and the back surface of the substrate.

[Aspect 8]

According to aspect 8, in the plating apparatus according to aspect 7, the substrate holder includes a first power supply mechanism for supplying a current to the front surface of the substrate and a second power supply mechanism for supplying a current to the back surface of the substrate. According to the plating apparatus of aspect 8, it is possible to control currents for the front surface and the back surface of the substrate independently of each other.

[Aspect 9]

According to aspect 9, in the plating apparatus according to aspect 7 or 8, the sealing part includes a bag body configured to inflate by introducing a gas thereinto. According to the plating apparatus of aspect 9, it is possible to cause the bag body to inflate by introducing the gas into the bag body to thereby seal the holder holding section.

[Aspect 10]

According to aspect 10, in the plating apparatus according to aspect 7 or 8, the sealing part includes a rotatable wedge member. According to the plating apparatus of aspect 8, it is possible to seal the holder holding section by rotating the wedge member.

[Aspect 11]

According to aspect 11, in the plating apparatus according to any one of aspects 7 to 10, the holder holding section includes a contact sensor. According to the plating apparatus of aspect 11, the contact sensor can detect whether or not the substrate holder is disposed appropriately in the plating tank.

[Aspect 12]

According to aspect 12, the plating apparatus according to any one of aspects 7 to 11 further includes an external tank that receives a plating liquid overflowing from the plating tank.

[Aspect 13]

According to aspect 13, in the plating apparatus according to aspect 12, the external tank includes a removable partition member for dividing the external tank into a first portion and a second portion.

[Aspect 14]

According to aspect 14, in the plating apparatus of aspect 13, the plating liquid overflowing from the first portion of the plating tank is received by the first portion of the external tank and the plating liquid overflowing from the second portion of the plating tank is received by the second portion of the external tank. According to aspect 14, it is possible to prevent the plating liquid used for the plating process on the front surface of the substrate and the plating liquid used for the plating process on the back surface from being mixed in the external tank as well.

[Aspect 15]

According to aspect 15, the plating apparatus according to aspect 14 further includes a first circulation mechanism for causing the plating liquid to circulate from the first portion of the external tank to the first portion of the plating tank and a second circulation mechanism for causing the plating liquid to circulate from the second portion of the external tank to the second portion of the plating tank. According to aspect 15, it is possible to cause the plating liquid used for the plating process on the front surface of the substrate and the plating liquid used for the plating process on the back surface to circulate independently of each other.

[Aspect 16]

According to aspect 16, the plating apparatus according to any one of aspects 7 to 15 further includes a first buffer tank for temporarily storing the plating liquid at the first portion of the plating tank and a second buffer tank for temporarily storing the plating liquid at the second portion of the plating tank. According to aspect 16, it is possible to store the plating liquid used for the plating process on the front surface of the substrate and the plating liquid used for the plating process on the back surface respectively and individually.

[Aspect 17]

According to aspect 17, a plating method is provided, the method including a step of holding a substrate in a substrate holder such that a plating target region on a front surface and a plating target region of a back surface of the substrate are exposed, a step of disposing the substrate holder holding the substrate in a plating tank, a step of dividing the plating tank into fluidically separated first and second portions by the substrate holder holding the substrate, a step of supplying a first plating liquid to the first portion of the plating tank, a step of supplying a second plating liquid to the second portion of the plating tank, a step of applying a plating process to the plating target region on the front surface of the substrate using the first plating liquid, and a step of applying a plating process to the plating target region on the back surface of the substrate using the second plating liquid. According to the method of aspect 17, it is possibly to divide the plating tank into a plurality of regions using the substrate holder that holds the substrate and separate the plating liquid used for the plating process on the front surface of the substrate from the plating liquid used for the plating process on the back surface. It is thereby possible to execute different types of control for the plating liquid used for the plating process on the front surface of the substrate and the plating liquid used for the plating process on the back surface. For example, plating liquids varying in concentration and temperature can be used for the front surface and the back surface of the substrate.

[Aspect 18]

According to aspect 18, in the plating method according to aspect 27, the step of plating the front surface of the substrate and the step of plating the back surface of the substrate are controlled independently of each other.

[Aspect 19]

According to aspect 19, in the plating method according to aspect 18, the first plating liquid and the second plating liquid are controlled independently of each other.

[Aspect 20]

According to aspect 20, in the plating method according to any one of aspects 17 to 19, the first plating liquid and the second plating liquid are different plating liquids.

[Aspect 21]

According to aspect 21, a computer program is provided for causing the method according to aspect 18 or 19 to be executed. According to aspect 21, the plating method according to the present disclosure can be automatically executed by causing a computer to control the plating apparatus.

[Aspect 22]

According to aspect 22, a computer readable recording medium is provided in which the computer program according to aspect 21 is recorded. According to aspect 22, it is possible to implement a control apparatus that controls the plating apparatus by installing the computer program in a common computer.

### BRIEF DESCRIPTION OF DRAWINGS

FIG. 1 is a schematic view illustrating an embodiment of a plating apparatus;

FIG. 2 is a schematic diagram illustrating an example of a substrate holder used for the plating apparatus according to the embodiment;

FIG. 3A is a side view schematically illustrating a state before the substrate holder is inserted into a plating tank according to the embodiment;

FIG. 3B is a top view of the plating tank seen from a line segment 3B in FIG. 3A;

FIG. 4A is a side view schematically illustrating a state in which the substrate holder is inserted in the plating tank according to the embodiment;

FIG. 4B is a top view of the plating tank seen from a line segment 4B in FIG. 4A;

FIG. 5A is a diagram illustrating a sealing structure between a guide concave portion of the plating tank and a sealing member of the substrate holder;

FIG. 5B is a diagram illustrating a state when the substrate holder is inserted into the plating tank and before a gas is inserted into a bag body which is the sealing member;

FIG. 5C is a diagram illustrating a state in which the gas is supplied into the bag body and the guide concave portion is closed and sealed;

FIG. 6A is a side view schematically illustrating an interior of the plating tank during a plating process according to the embodiment;

FIG. 6B is a schematic diagram of the plating apparatus shown in FIG. 6A seen from above;

FIG. 7 is a front view schematically illustrating an anode holder according to the embodiment;

FIG. 8 is a diagram illustrating an anode mask when the aperture diameter is relatively small;

FIG. 9A is a top view schematically illustrating part of the substrate holder and the sealing member according to the embodiment;

FIG. 9B is a side view schematically illustrating the sealing member shown in FIG. 9A;

FIG. 9C is a diagram illustrating a state when the substrate holder is inserted into the plating tank and before the guide concave portion of the plating tank is sealed with the sealing member;

FIG. 9D is a diagram describing the sealing member provided in the substrate holder according to the embodiment;

FIG. 10 is a flowchart illustrating a plating method according to the embodiment;

FIG. 11A is a diagram illustrating a structure of the sealing member according to the embodiment and is a cross-sectional view seen from a direction shown by an arrow 11 in FIG. 2; and

FIG. 11B is a diagram illustrating a structure of the sealing member according to the embodiment and is a cross-sectional view seen from a direction shown by an arrow 11 in FIG. 2.

### DESCRIPTION OF EMBODIMENTS

Hereinafter, an embodiment of a plating apparatus and a substrate holder used for the plating apparatus according to the present invention will be described along with the accompanying drawings. In the accompanying drawings, identical or similar elements are assigned identical or similar reference numerals and duplicate description regarding the identical or similar elements may be omitted in the description of each embodiment. Features shown in each embodiment may be applicable to other embodiments in so far as they are not inconsistent with each other. Note that in the present specification, the term “substrate” includes not only a semiconductor substrate, glass substrate or printed circuit substrate but also a magnetic recording medium, magnetic recording sensor, mirror, optical element, micro mechanical element or partially fabricated integrated circuit.

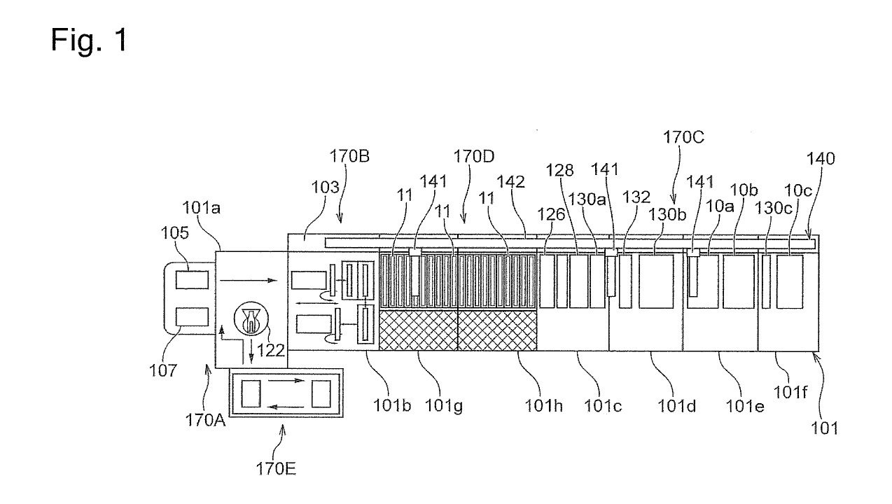

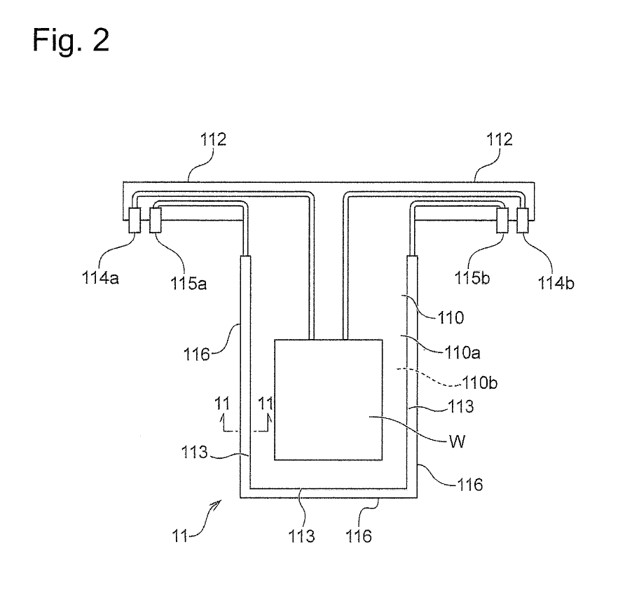

FIG. 1 is a schematic view illustrating an embodiment of the plating apparatus. As shown in FIG. 1, the plating apparatus is provided with a frame 101, a control section 103 that controls operation of the plating apparatus, a loading/unloading section 170A that loads or unloads a substrate W (see FIG. 2), a substrate setting section (mechanical chamber) 170B that sets the substrate W in a substrate holder 11 (see FIG. 2) and removes the substrate W from the substrate holder 11, a processing section (pre-processing chamber, plating chamber) 170C that plates the substrate W, a holder storage section (stocker chamber) 170D that stores the substrate holder 11 and a cleaning section 170E that cleans and dries the plated substrate W. The plating apparatus according to the present embodiment is an electrolytic plating apparatus that plates both a front surface and a back surface of the substrate W with a metal by causing a current to flow through a plating liquid. The substrate W to be processed in the present embodiment is a semiconductor package substrate or the like. Furthermore, a conductive layer made up of a seed layer is formed on the front surface side and the back surface side of the substrate W respectively, and further, a resist layer is formed in a region where a pattern surface is formed on the conductive layer, and trenches and vias are formed in advance in the resist layer. In the present embodiment, a substrate provided with no through hole that connects the front surface and the back surface of the substrate is the processing target, and a so-called non-through-hole substrate is the processing target.

As shown in FIG. 1, the frame 101 is composed of a plurality of frame members 101a to 101h and these frame members 101a to 101h are configured to be connectable to each other. Components of the loading,/unloading section 170A are arranged on the first frame member 101a, components of the substrate setting section 170B are arranged on the second frame member 101b, components of the processing section 1700 are arranged on the third frame member 101c to sixth frame member 101f and components of the holder storage section 170D are arranged on the seventh frame member 101g and eighth frame member 101h.

The loading/unloading section 170A is provided with a loading stage 105 on which a cassette (not shown) housing a substrate W before plating is mounted and an unloading stage 107 on which a cassette (not shown) that receives a plated substrate W in the processing section 170C is mounted. The loading/unloading section 170A is further provided with a substrate transporting apparatus 122 made up of a transporting robot that transports the substrate W.

The substrate transporting apparatus 122 is configured to access the cassette mounted on the loading stage 105, remove the substrate W before plating from the cassette and deliver the substrate W to the substrate setting section 170B. The substrate setting section 170B sets the substrate W before plating in the substrate holder 11 and removes the plated substrate W from the substrate holder 11.

A pre-wet tank 126, a pre-soak tank 128, a first rinsing tank 130a, a blow tank 132, a second rinsing tank 130b, a first plating tank 10a, a second plating tank 10b, a third rinsing tank 130c and a third plating tank 10c are arranged in the processing section 170C. These tanks 126, 128, 130a, 132, 130b, 10a, 10b, 130c and 10c are arranged in this order.

In the pre-wet tank 126, the substrate W is soaked in pure water as preparations for pre-processing. In the pre-soak tank 128, an oxide film on the surface of a conductive layer such as a seed layer formed on the front surface of the substrate W is removed by etching using a chemical solution. In the first rinsing tank 130a, the pre-soaked substrate W is cleaned with a cleaning liquid (e.g., pure water).

In at least one of the plating tanks 10: the first plating tank 10a, the second plating tank 10b and the third plating tank 10c, both sides of the substrate W are plated. Note that the number of plating tanks 10 in the embodiment shown in FIG. 1 is three, but any number of plating tanks 10 may be provided as another embodiment.

In the second rinsing tank 130b, the substrate W plated in the first plating tank 10a or second plating tank 10b is cleaned together with the substrate holder 11 with a cleaning liquid (e.g., pure water). In the third rinsing tank 130c, the substrate W plated in the third plating tank 10c is cleaned together with the substrate holder 11 with a cleaning liquid (e.g., pure water). In the blow tank 132, the cleaned substrate W is subjected to liquid draining.

The pre-wet tank 126, the pre-soak tank 128, the rinsing tanks 130a to 130c, and the plating tanks 10a to 10c are treatment tanks in which a treatment liquid (liquid) can be contained. These treatment tank are each provided with a plurality of treatment cells that contain a treatment liquid, but without being limited to this embodiment, the treatment tank may be provided with a single treatment cell. Furthermore, at least some of these treatment tanks may be provided with a single treatment cell and the other treatment tanks may be provided with a plurality of treatment cells.

The plating apparatus is further provided with a transporting machine 140 that transports the substrate holder 11. The transporting machine 140 is configured to be movable between the components of the plating apparatus. The transporting machine 140 is provided with a fixed base 142 extending in the horizontal direction from the substrate setting section 170B to the processing section 170C and a plurality of transporters 141 configured to be movable along the fixed base 142.

These transporters 141 each include a movable section (not shown) for holding the substrate holder 11 and are configured to hold the substrate holder 11. The transporters 141 are each configured to transport the substrate holder 11 among the substrate setting section 170B, the holder storage section 170D and the processing section 170C and further move the substrate holder 11 together with the substrate W in the vertical direction. An example of a moving mechanism of the transporter 141 can be a combination of a motor and a rack and pinion. Note that three transporters are provided in the embodiment shown in FIG. 1, but any number of transporters may be adopted as other embodiments.

A configuration of the substrate holder 11 will be described with reference to FIG. 2. FIG. 2 is a schematic diagram illustrating an example of the substrate holder used for the plating apparatus according to the embodiment. As shown in FIG. 2, the substrate holder 11 is provided with a body part 110 that holds the substrate W and an arm portion 112 provided at a top end of the body part 110. The body part 110 is constructed of a first member 110a and a second member 110b. The substrate holder 11 causes the first member 110a and the second member Hob to grasp the substrate W to thereby hold the substrate W. The first member 110a and the second member 110b each define an opening and hold the substrate W such that plated surfaces of the front surface and the back surface of the substrate W are exposed respectively. In other words, the first member 110a and the second member 110b hold the substrate W by sandwiching only a peripheral portion of the substrate W from both sides. The substrate holder 11 is transported with the arm portion 112 being held to the transporter 141. The substrate holder 11 shown in FIG. 2 is intended to hold a rectangular substrate W, but without being limited to this, the substrate holder 11 may also be configured to hold a circular substrate. In that case, the openings formed in the first member 110a and the second member 110b also become circular. Alternatively, the substrate W can also be a polygonal substrate such as a hexagonal one. In this case, the openings formed in the first member 110a and the second member 110b may likewise become polygonal.

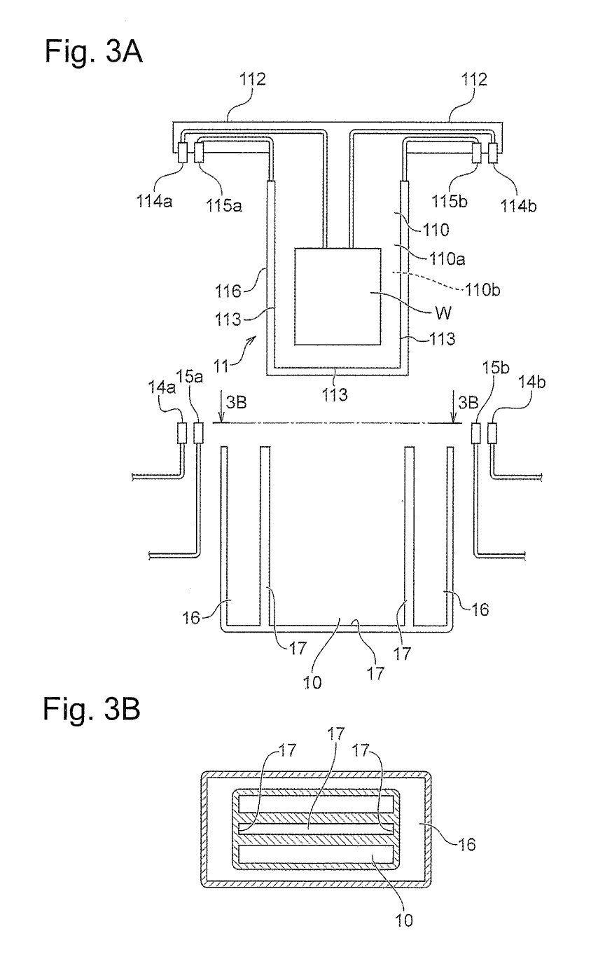

A sealing member 116 is provided on at least part of a peripheral portion 113 of the body part 110 of the substrate holder 11 so as to protrude from the peripheral portion 113 of the first member 110a and the second member 110b. Note that the peripheral portion here refers to a side face and a bottom surface of the substrate holder 11. Although details will be described later, the sealing member 116 is intended to divide the plating tank 10 on the front surface side and the back surface side of the substrate holder 11 when the substrate holder 11 is disposed in the plating tank 10. Therefore, when the substrate holder 11 is soaked in the plating tank 10, the sealing member 116 is provided over the whole part soaked in the plating liquid. Furthermore, the sealing member 116 may be provided continuously without a gap such that the plating tank 10 may be divided so as to be fluidically separated. The sealing member 116 can be a bag body 117 formed of an elastic material such as rubber and the bag body 117 is configured such that a gas such as air may be sealed therein. When this sealing member 116 is configured as the bag body 117, it can be formed of an elastic material having electrically insulating properties. By coating the surface of the bag body 117 (e.g., rubber material) with an organic material containing paraxylylene such as parylene (registered trademark), it is also possible to improve sealing properties and/or electrical insulating properties. Alternatively, as the elastic material, it is possible to improve sealing properties of the sealing member 116 by using a material providing relatively high wettability for the front surface of the bag body 117, for example, a material including at least one of (i) polyvinylidene fluoride (PVDF), (ii) polytetrafluoroethylene (PTFE), (iii) copolymer including at least one of polyvinylidene fluoride (PVDF) and polytetrafluoroethylene (PTFE) and (iv) elastic member made of two-liquid fluorine rubber-based sealing member. The sealing member 116 makes it possible to fix the substrate holder 11 at a predetermined position in the plating tank 10 and thereby prevent deterioration of uniformity of the plating film thickness within the substrate surface caused by insufficient positioning of the substrate holder 11. Note that the sealing member 116 of the substrate holder 11 is provided at a position of the peripheral portion 113 of the substrate holder 11 corresponding to the holder holding section 17 of the plating tank 10 (see FIG. 3A and FIG. 3B) so as to divide the plating tank 10 between the front side and the back side of the substrate holder 11. For example, when the height of the holder holding section 17 is determined in correspondence with a water level of the plating liquid in the plating tank 10, the sealing member 116 need not be provided on the whole peripheral portion 113 of the body part 110, but the sealing member 116 can be provided so as to protrude from the peripheral portion 113 of the substrate holder 11 so as to correspond to the position of the holder holding section 17 of the plating tank 10.

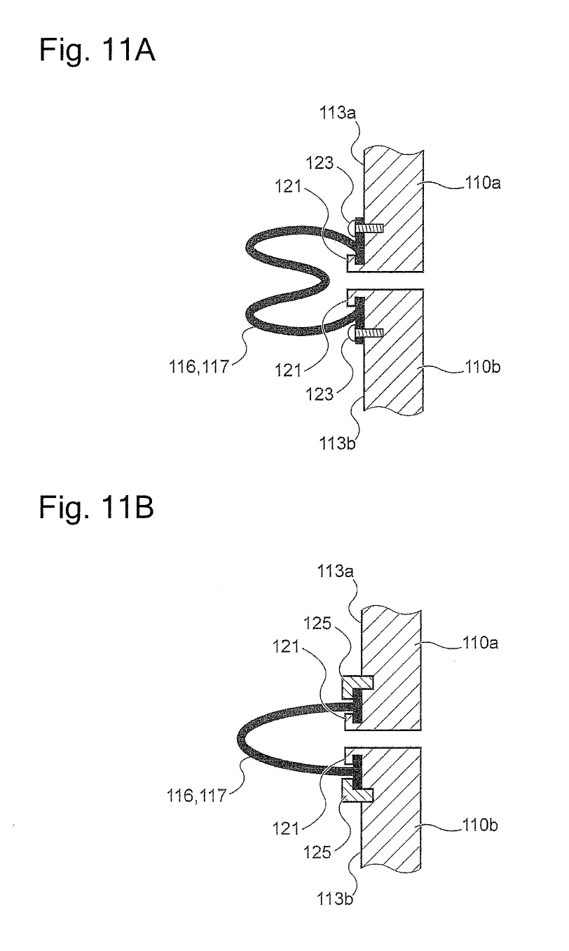

FIG. 11A is a diagram illustrating a structure of the sealing member 116 according to the embodiment and is a cross-sectional view seen from a direction shown by an arrow 11 in FIG. 2. In the embodiment shown in FIG. 11A, the sealing member 116 is formed of the bag body 117 which is an elastic member. As shown in FIG. 11A, hook-like protrusion portions 121 are provided at end portions of the first member 110a and the second member 110 of the substrate holder 11 respectively and two end portions of the bag body 117 are disposed respectively here. Furthermore, in the embodiment in FIG. 11A, screws 123 are provided adjacent to the protrusion portions 121 and the bag body 117 is fixed at the end portions of the first member 110a and the second member 110b of the substrate holder 11 using the screws 123. The gas for inflating the bag body 117 can be supplied from a gap between the first member 110a and the second member 110b.

FIG. 11B is a diagram illustrating a structure of the sealing member 116 according to the embodiment and is a cross-sectional view seen from the direction shown by the arrow 11 in FIG. 2. In the embodiment shown in FIG. 11B, the sealing member 116 is formed of the bag body 117 which is an elastic member. As shown in FIG. 11B, hook-like protrusion portions 121 are provided at end portions of the first member 110a and the second member 110b of the substrate holder 11 respectively and two end portions of the bag body 117 are disposed respectively here. Furthermore, in the embodiment in FIG. 11B, engagement members 125 are provided adjacent to the protrusion portions 121, and the protrusion portions 121 and the engagement members 125 fix the bag body 117 at the end portions of the first member 110a and the second member 110b of the substrate holder 11. The gas for inflating the bag body 117 can be supplied from a gap between the first member 110a and the second member 110b.

When the substrate W held to the substrate holder 11 is soaked in a treatment liquid in each treatment tank, the arm portion 112 is disposed above an arm receiving member (not shown) of each treatment tank. Since the plating tanks 10a to 10c are electrolytic plating tanks in the present embodiment, when a power supply contact (connector section) 114 provided on the arm portion 112 comes into contact with an electric contact 14 (see FIG. 3A) provided in an arm receiving member of the plating tank 10, a current is supplied from an external power supply to the front surface and the back surface of the substrate W. In the substrate holder 11 shown in FIG. 2, two power supply contacts 114 are provided on the arm portion 112, one power supply contact 114a is intended to supply a current to the front surface of the substrate W and the other power supply contact 114b is intended to supply a current to the back surface of the substrate W.

Furthermore, the arm portion 112 of the substrate holder 11 is provided with an air supply contact 115 to supply a gas to the bag body 117 which is the sealing member 116. When the arm portion 112 is disposed on the arm receiving member of the plating tank, the arm portion 112 is connected to a gas supply contact 15 (see FIG. 3A) provided on the arm receiving member of the plating tank 10 and can supply the gas from an external gas source to the bag body 117. The substrate holder 11 shown in FIG. 2 is provided with two air supply contacts 115, but the number of air supply contacts 115 may be one.

The plated substrate W is transported together with the substrate holder 11 to the substrate setting section 170B by the transporter 141 and is removed from the substrate holder 11 at the substrate setting section 170B. This substrate W is transported to the cleaning section 170E by the substrate transporting apparatus 122 and is cleaned and dried by the cleaning section 170E. After that, the substrate W is returned to a cassette mounted on the unloading stage 107 by the substrate transporting apparatus 122.

FIG. 3A is a side view schematically illustrating a state before the substrate holder 11 is inserted into the plating tank 10. FIG. 3B is a top view of the plating tank 10 seen from the line segment 3B in FIG. 3A. The plating tank 10 can be any one of the aforementioned plating tanks 10a to 10c. As shown in FIG. 3A and FIG. 3B, the plating apparatus includes the plating tank 10 and an external tank 16 that receives a plating liquid overflowing from the plating tank 10. The holder holding section 17 for receiving the substrate holder 11 is provided on the mutually facing side walls and the bottom surface of the plating tank 10. As an embodiment, the holder holding section 17 is configured as the guide concave portion 17 for receiving the substrate holder 11. The substrate holder 11 is disposed inside the plating tank 10 so as to engage with the guide concave portion 17 of the plating tank 10.

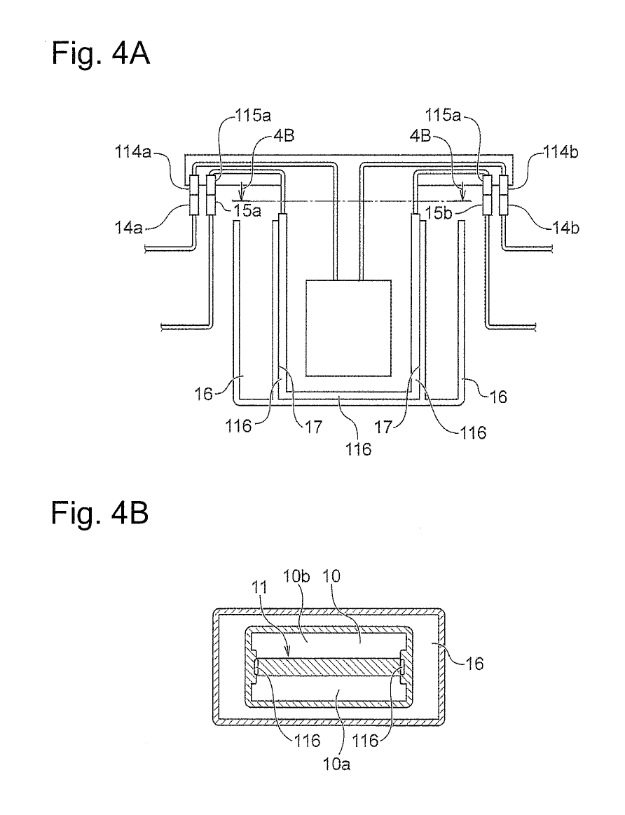

FIG. 4A is a side view schematically illustrating a state in which the substrate holder 11 is inserted into the plating tank 10. FIG. 4B is a top view of the plating tank 10 seen from a line segment 4B in FIG. 4A. As shown in FIG. 4A and FIG. 4B, the substrate holder 11 is inserted such that the sealing member 116 engages with the guide concave portion 17 of the plating tank 10. When the substrate holder 11 is inserted into the plating tank 10, the power supply contact 114a is connected to the electric contact 14a and the power supply contact 114b is connected to the electric contact 14b so as to be able to supply a current to the front surface and the back surface of the substrate W. Furthermore, when the substrate holder 11 is inserted into the plating tank 10, the air supply contact 115a is connected to the gas supply contact 15a and the air supply contact 115b is connected to the gas supply contact 15b so as to be able to supply a gas to the bag body 117 which is the sealing member 116.

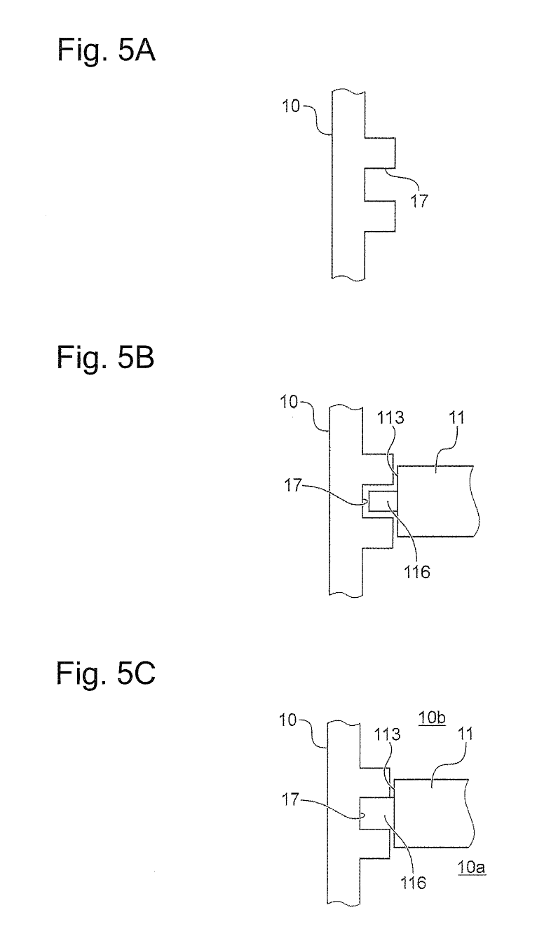

FIG. 5A is a diagram illustrating a sealing structure between the guide concave portion 17 of the plating tank 10 and the sealing member 116 of the substrate holder 11. FIG. 5A illustrates part of a side wall of the plating tank 10 in which the guide concave portion 17 is provided. FIG. 5B is a diagram illustrating a state when the substrate holder 11 is inserted into the plating tank 10 and before a gas is inserted into the bag body 117 which is the sealing member 116. As shown in FIG. 5B, while the substrate holder 11 is inserted in the plating tank 10, there is some gap between the sealing member 116 of the substrate holder 11 and the guide concave portion 17 of the plating tank 10. In this state, if a gas is supplied to the bag body 117 which is the sealing member 116 via the gas supply contacts 15a and 15b, the bag body 117 inflates, and the bag body 117 closes and thereby seals the guide concave portion 17. FIG. 5C illustrates a state in which the gas is supplied to the bag body 117 and the guide concave portion 17 is closed and sealed. Note that a contact sensor for detecting a contact state may be provided on the front surface of the guide concave portion 17 so as to detect whether sealing is in progress appropriately or not. If sealing is not appropriately performed, the gas may be removed from the bag body 117 and air may be supplied again.

When the substrate holder 11 is inserted into the plating tank 10, and the guide concave portion 17 is closed and sealed with the sealing member 116, the plating tank 10 is divided into the first portion 10a on the front surface side of the substrate holder 11 and the second portion 10b on the back surface side. Sealed with the sealing member 116, the first portion 10a and the second portion 10b of the plating tank 10 are fluidically separated from each other, and the plating liquid in the first portion 10a and the plating liquid in the second portion 10b are fluidically separated from each other. Therefore, the front surface of the substrate W is plated with a plating liquid in the first portion 10a and the back surface is plated with a plating liquid in the second portion 10b. Note that as for the plating liquid, for example, when a copper plating process is performed, it is possible to use not only copper sulfate which becomes a copper source but also a plating liquid containing a polymer component (inhibitor) of an organic additive, carrier component (accelerator), leveler component (inhibitor) in a base liquid containing sulfuric acid and chlorine. Examples of this organic additive include nitrogen-containing organic compound, sulfur-containing organic compound, oxygen-containing organic compound.

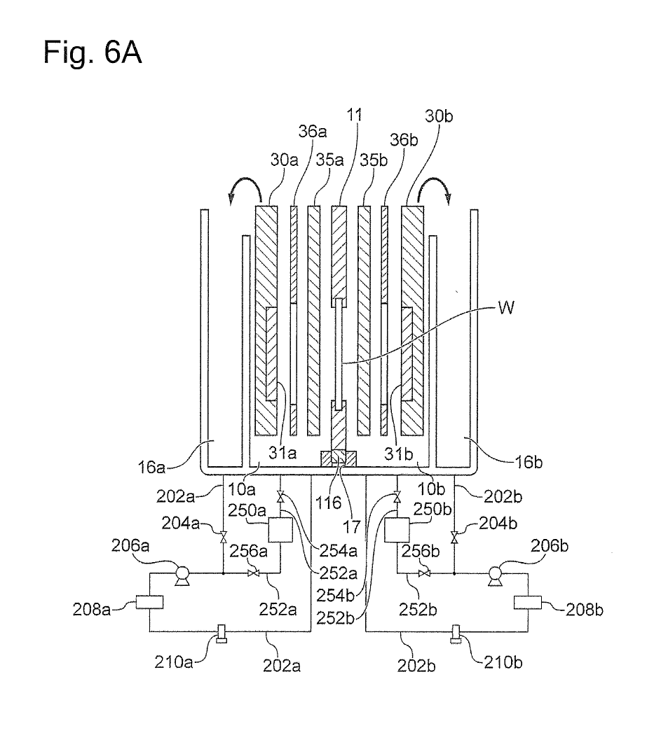

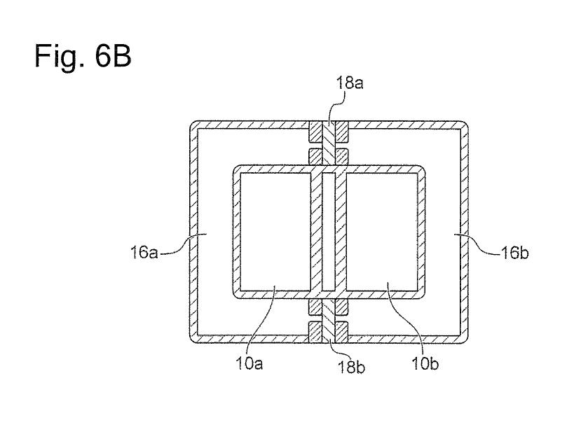

FIG. 6A is a side view schematically illustrating a situation in the plating tank 10 during a plating process. In FIG. 6A, the first portion 10a of the plating tank 10 is shown on the left side of the substrate holder 11 and the substrate W, and the second portion 10b is shown on the right side. During the plating process, a first anode holder 30a is disposed in the first portion 10a of the plating tank 10 so as to face the front surface of the substrate W and a second anode holder 30b is disposed in the second portion 10b of the plating tank 10 so as to face the back surface of the substrate W.

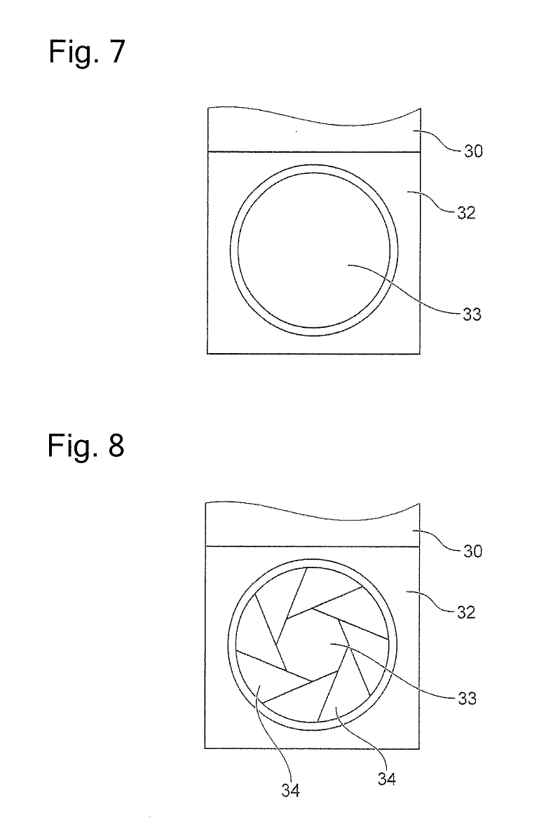

FIG. 7 is a front view schematically illustrating the anode holder 30 according to the embodiment. The anode holder 30 shown in FIG. 7 can be adopted as the aforementioned first anode holder 30a and second anode holder 30b. The anode holder 30 includes an anode mask 32 to adjust an electric field between an anode 31 and the substrate W. The anode mask 32 is a substantially tabular member made of, for example, a dielectric material and is provided on the front of the anode holder 30. Here, the front surface of the anode holder 30 refers to the surface of the side facing the substrate holder 11. That is, the anode mask 32 is disposed between the anode 31 and the substrate holder 11. The anode mask 32 has an opening 33 at substantially the center through which a current flowing between the anode 31 and the substrate W passes. The diameter of the opening 33 is preferably smaller than the diameter of the anode 31. The anode mask 32 is configured to be able to adjust the diameter of the opening 33. FIG. 7 illustrates the anode mask 32 when the diameter of the opening 33 is relatively large. Note that the shape of the opening 33 of the anode mask 32 is not limited to the circular shape, but can vary depending on the shape or the like of the substrate W.

FIG. 8 illustrates the anode mask 32 when the diameter of the opening 33 is relatively small. The anode mask 32 includes a plurality of aperture blades 34 configured to be able to adjust the opening 33. The aperture blades 34 jointly define the opening 33. Each of the aperture blades 34 can enlarge or contract the diameter of the opening 33 through a structure similar to a diaphragm mechanism of a camera.

The anode 31 held to the anode holder 30 is preferably an insoluble anode. In the case where the anode 31 is an insoluble anode, the anode 31 is not dissolved and the shape of the anode 31 never changes even when a plating process advances. For this reason, since a positional relationship (distance) between the anode mask 32 and the surface of the anode 31 does not change, it is possible to prevent an electric field between the anode 31 and the substrate W from changing as the positional relationship between the anode mask 32 and the surface of the anode 31 changes. On the other hand, in the plating apparatus shown in FIG. 6A, a configuration may be adopted in which moving mechanisms are connected to the first anode holder 30a and the second anode holder 30b respectively so that the distance between the substrate W and the first anode holder 30a, and the distance between the substrate W and the second anode holder 30b may be changed.

In the plating apparatus according to the embodiment shown in FIG. 6A, a first intermediate mask 36a is provided between the first anode holder 30a and the substrate holder 11. Furthermore, a second intermediate mask 36b is provided between the second anode holder 30b and the substrate holder 11. These intermediate masks 36a and 36b are intended to adjust the diameters of the openings provided in the intermediate masks 36a and 36b, and thereby adjust the electric field between the anode 31 and the substrate W through a structure similar to that of the anode mask 32 shown in FIG. 7 and FIG. 8. As an embodiment, a configuration may be adopted in which moving mechanisms are connected to the first intermediate mask 36a and the second intermediate mask 36b respectively so that the distance between the substrate W and the first intermediate mask 36a and the distance between the substrate W and the second intermediate mask 36b may be changed. Note that in the case where an insoluble anode is adopted, since a plating metal needs to be continuously supplied into the plating liquid, it is also possible to provide a mechanism for supplying the plating metal in a circulation mechanism which will be described later.

In the plating apparatus according to the embodiment shown in FIG. 6A, a first paddle 35a is provided between the first anode holder 30a and the substrate holder 11 to stir the plating liquid in the vicinity of the plated surface of the substrate W. Furthermore, a second paddle 35b is provided between the second anode holder 30b and the substrate holder 11 to stir the plating liquid in the vicinity of the plated surface of the substrate W. These paddles 35a and 35b can be substantially bar-like members and can be provided in a plating process tank 52 so as to be oriented in the vertical direction. The paddles 35a and 35b are configured to be able to horizontally move along the plated surface of the substrate W through a drive apparatus (not shown).

Note that when different processes are performed on the front surface side and the back surface side of the substrate W or when different processes are performed on the front surface side and the back surface side of the substrate W, and the plating times are preferably set to optimal times on the front surface side and the back surface side, the control section 103 may control the drive apparatus of the paddle 35 so that the paddles 35a and 35b perform appropriate operations varying between the first portion 10a and the second portion 10b of the plating tank 10 respectively. Note that these paddles can be configured to reciprocate at, for example, average 70 to 400 cm/sec.

Furthermore, when the substrate W, which is a treatment target is a thin-film substrate, a configuration may be adopted in which the flow of the plating liquid in the first portion 10a of the plating tank 10 and the flow of the plating liquid in the second portion 10b of the plating tank 10 may be adjusted to substantially the same flow rate, and a rectification plate (not shown) may be provided at the bottom part of the first portion 10a of the plating tank and at the bottom part of the second portion 10b respectively so as to prevent the substrate W held to the substrate holder 11 from being distorted. Alternatively, a configuration may also be adopted in which a plating liquid supply mechanism (not shown) provided at the bottom part of the first portion 10a of the plating tank 10 and at the bottom part of the second portion 10b respectively so that a plating liquid is supplied from the plating liquid supply mechanism to the substrate W so that the plating liquid is jetted from a nozzle).

FIG. 6B is a schematic diagram of the plating apparatus shown in FIG. 6A seen from above. Note that the substrate holder 11, the anode holders 30a and 30b, the paddles 35a and 35b, and the intermediate masks 36a and 36b are omitted in FIG. 6B for illustrative clarification. As shown in FIG. 6B, two partition members 18a and 18b are provided in the external tank 16 of the plating apparatus. As shown in FIG. 6B, the partition members 18a and 18b are arranged on an extension of a boundary on which the substrate holder 11 divides the plating tank 10 into the first portion 10a and the second portion 10b in the external tank 16. The external tank 16 is divided by the partition members 18a and 18b into a first portion 16a and a second portion 16b. The partition members 18a and 18b fluidically separate the first portion 16a from the second portion 16b of the external tank 16. The heights of the partition members 18a and 18b are greater than the height of the side wall of the plating tank 10. For this reason, the plating liquid overflowing from the first portion 10a of the plating tank 10 is received by the first portion 16a of the external tank 16 and the plating liquid overflowing from the second portion 10b of the plating tank 10 is received by the second portion 16b of the external tank 16.

The plating apparatus according to the embodiment shown in FIG. 6A includes two circulation mechanisms to circulate the plating liquid. A first circulation mechanism shown in FIG. 6A is intended to circulate the plating liquid between the first portion 10a of the plating tank 10 and the first portion 16a of the external tank 16, and the second circulation mechanism is intended to circulate the plating liquid between the second portion 10b of the plating tank 10 and the second portion 16b of the external tank 16. As shown in FIG. 6A, the first circulation mechanism is provided with a first circulation line 202a to connect the first portion 16a of the external tank 16 and the first portion 10a of the plating tank 10. The first circulation line 202a is provided with a valve 204a which can open/close the first circulation line 202a. The valve 204a can be, for example, a solenoid valve and may be configured to be able to control opening/closing of the first circulation line 202a under the control section 103 (see FIG. 1). The first circulation line 202a is provided with a first pump 206a which can circulate the plating liquid from the first portion 16a of the external tank 16 through the first circulation line 202a to the first portion 10a of the plating tank 10. The first circulation line 202a is provided with a first temperature control apparatus 208a which can control the temperature of the plating liquid passing through the first circulation line 202a. For example, a thermometer (not shown) may be provided in the first portion 10a of the plating tank 10 and the control section 103 may control the first temperature control apparatus 208a according to the temperature of the plating liquid of the first portion 10a measured by the thermometer. The first circulation line 202a is provided with a first filter 210a which can remove a solid matter of the plating liquid passing through the first circulation line 202a.

The plating apparatus shown in FIG. 6A includes a first buffer tank 250a to temporarily store the plating liquid of the first portion 10a of the plating tank 10. As shown in FIG. 6A, an inlet of the first buffer tank 250a is connected to a first buffer line 252a connected to the first portion 10a of the plating tank 10. An outlet of the first buffer tank 250a is connected to the first circulation line 202a. A valve 254a and a valve 256a are provided on the first buffer line 252a on the inlet side and the outlet side of the first buffer tank 250a respectively. The valve 254a and the valve 256a may be solenoid valves and the control section 103 (see FIG. 1) may be configured to be able to control opening/closing of the valves 254a and 256a. When the plating liquid in the first portion 10a of the plating tank 10 is evacuated to the first buffer tank 250a (e.g., when the plating process ends and the substrate holder 11 and the substrate W are raised from the plating tank 10), the valve 254a is opened and the plating liquid is evacuated to the first buffer tank 250a. When the plating liquid is supplied to the first portion 10a of the plating tank 10 from the first buffer tank 250a again (e.g., when the substrate holder 11 is disposed in the plating tank 10 and a new plating process is started), the valve 256a is opened and the plating liquid can be supplied to the first portion 10a of the plating tank 10 via the first circulation line 202a.

As shown in FIG. 6A, a second circulation mechanism is provided with a second circulation line 202b to connect the second portion 16b of the external tank 16 and the second portion 10b of the plating tank 10. The second circulation line 202b is provided with a valve 204b which can open/close the second circulation line 202b. The valve 204b can be, for example, a solenoid valve and the control section 103 (see FIG. 1) may be configured to be able to control opening/closing of the second circulation line 202b. A second pump 206b is provided on the second circulation line 202b, which can circulate the plating liquid from the second portion 16b of the external tank 16 through the second circulation line 202b to the second portion 10b of the plating tank 10. A second temperature control apparatus 208b is provided on the second circulation line 202b, which can control the temperature of the plating liquid passing through the second circulation line 202b. For example, a thermometer (not shown) may be provided in the second portion 10b of the plating tank 10 so that the control section 103 may control the second temperature control apparatus 208b according to the temperature of the plating liquid of the second portion 10b measured by this thermometer. A second filter 210b is provided on the second circulation line 202b, which can remove a solid matter of the plating liquid passing through the second circulation line 202b.

The plating apparatus shown in FIG. 6A includes a second buffer tank 250b to temporarily store the plating liquid of the second portion 10b of the plating tank 10. As shown in FIG. 6A, an inlet of the second buffer tank 250b is connected to the second buffer line 252b connected to the second portion 10b of the plating tank 10. An outlet of the second buffer tank 250b is connected to the second circulation line 202b. A valve 254b and a valve 256b are provided on the second buffer line 252b on the inlet side and the outlet side of the second buffer tank 250b respectively. The valve 254b and the valve 256b can be solenoid valves and the control section 103 (see FIG. 1) may be configured to be able to control opening/closing of the valves 254b and 256b. When the plating liquid in the second portion 10b of the plating tank 10 is evacuated to the second buffer tank 250b (e.g., when the plating process ends and the substrate holder 11 and the substrate W are raised from the plating tank 10), the valve 254b is opened and the plating liquid is evacuated to the second buffer tank 250b. When the plating liquid is supplied from the second buffer tank 250b to the second portion 10b of the plating tank 10 again (e.g., when the substrate holder 11 is disposed in the plating tank 10 and a new plating process is started), the valve 256b is opened and the plating liquid can be supplied to the second portion 10b of the plating tank 10 via the second circulation line 202b.

The plating apparatus according to the embodiment shown in FIG. 6A and FIG. 6B can be used to plate the front surface and the back surface of the substrate W. It is possible to fluidically separate the plating tank 10 using the substrate holder 11 to which the substrate W is held and divide the plating tank 10 into the first portion 10a positioned on the front surface side of the substrate W and the second portion 10b positioned on the back surface side of the substrate W. By so doing, the first portion 10a and the second portion 10b can shut off the electric field. Therefore, when different electrolytic plating processes are performed in the first portion 10a positioned on the front surface side of the substrate W and the second portion 10b positioned on the back surface side of the substrate W, it is possible to prevent a situation in which electric fields influence each other, preventing securing of the in-plane uniformity in thickness of the plating film formed on the substrate W. Therefore, it is possible to perform plating processes independently between a plating process on the front surface of the substrate W and a plating process on the back surface of the substrate W. For example, for the first portion 10a and the second portion 10b of the plating tank 10, it is possible to individually control the type of the anode disposed in the respective anode holders 30a and 30b, the size of the opening 33 of the anode mask 32, the sizes of the openings of the first intermediate masks 36a and 36b, currents or the like supplied to the front surface and the back surface of the substrate W. Furthermore, in the plating apparatus according to the embodiment shown in FIG. 6A and FIG. 6B, it is also possible to independently control the plating liquids used for the first portion 10a and the second portion 10b of the plating tank 10. For example, plating liquids varying in the type of the plating liquid and concentration of each component can be used. Furthermore, the aforementioned first circulation mechanism and second circulation mechanism can also independently control the temperature of the plating liquid. A drive apparatus (not shown) that drives the first paddle 35a and the second paddle 35b can independently control operations of the paddles.

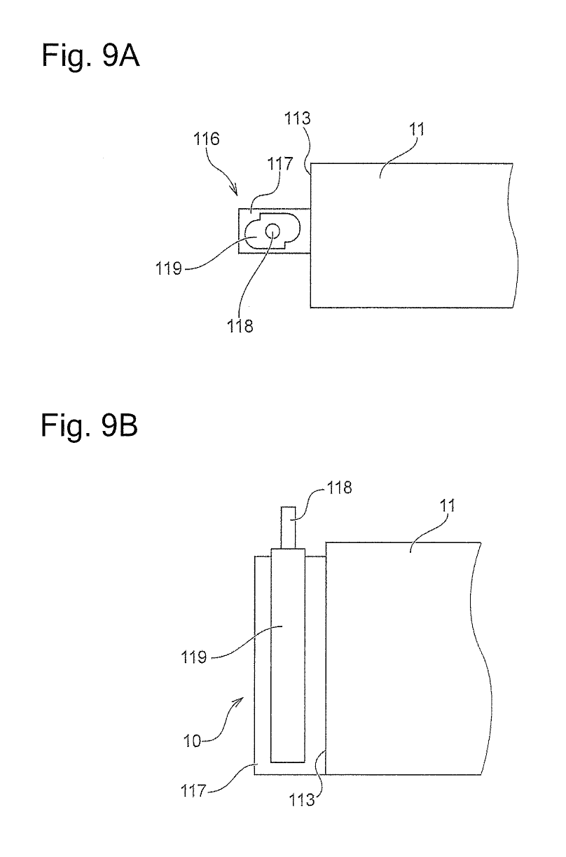

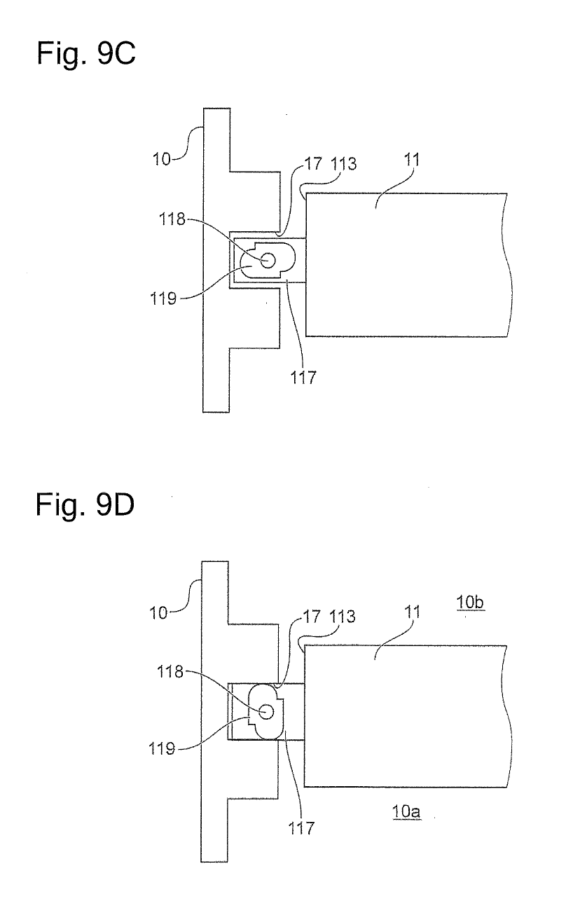

FIG. 94 to FIG. 9D are diagrams describing the sealing member 116 provided on the substrate holder 11 according to the embodiment. FIG. 9A is a top view schematically illustrating part of the substrate holder 11 and the sealing member 116. FIG. 9B is a side view schematically illustrating the sealing member 116 shown in FIG. 9A. In the embodiment shown in FIG. 9A to FIG. 9D, the sealing member 116 is provided with a bag body 117 formed of an elastic material such as rubber attached to the substrate holder 11 as in the case of the embodiment described together with FIG. 5A to FIG. 5C. However, in the embodiment shown in FIG. 9A to FIG. 9D, unlike the embodiment in FIG. 5A to FIG. 5C, no gas is sealed in the bag body 117. The sealing member 116 shown in FIG. 9A to FIG. 9D is provided with a rotating shaft 118 and a wedge member 119 connected to the rotating shaft 118 in the bag body 117. As shown in FIG. 9A, the wedge member 119 is provided with sizes varying in two directions orthogonal to each other centered on the rotating shaft 118. More specifically, the size in one direction of the wedge member 119 is a size in which the guide concave portion 17 of the plating tank 10 is not completely closed, while the other size is a size in which the guide concave portion 17 of the plating tank 10 can be completely closed. Therefore, by rotating the rotating shaft 118, it is possible to rotate the wedge member 119 and expand the bag body 117. FIG. 9C is a diagram illustrating a state when the substrate holder 11 is inserted into the plating tank 10 and before the sealing member 116 seals the guide concave portion 17 of the plating tank 10. FIG. 9D is a diagram illustrating a state in which the rotating shaft 118 is rotated by approximately 90 degrees from the state shown in FIG. 9C and the guide concave portion 17 of the plating tank 10 is sealed. Note that a contact sensor for detecting a contact state may be provided on the front surface of the guide concave portion 17 to detect whether or not sealing is in progress appropriately. If sealing is not in progress appropriately, the rotating shaft 118 may be rotated so that sealing may be performed appropriately. Note that when the sealing member shown in FIG. 9A to FIG. 9D is adopted, the air supply contacts 115a and 115b and the gas supply contacts 15a and 15b shown in FIG. 3A are unnecessary.

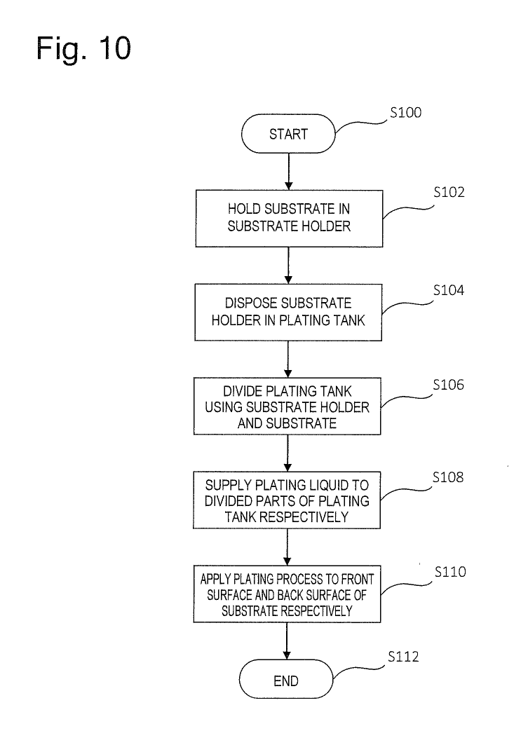

FIG. 10 is a flowchart illustrating a plating method according to an embodiment. The present plating method can be executed using the plating apparatus and the substrate holder 11 disclosed in the present specification. As shown in the flowchart in FIG. 10, a plating process is started (S100). In this stage, for example, the entire plating apparatus is started and the substrate W to be plated is prepared.

Next, the substrate W which is the plating target is held in the substrate holder 11. As described above, the substrate W is held to the substrate holder 11 so that both plated surfaces of the front surface and the back surface are exposed.

Next, the substrate holder 11 holding the substrate W is disposed in the plating tank 10 (S104). More specifically, the substrate holder 11 is disposed in the plating tank 10 so that the sealing member 116 of the substrate holder 11 is inserted into the guide concave portion 17 which is the holder holding section of the plating tank 10. The substrate holder 11 is moved, for example, using the transporters 141 in FIG. 1. Note that before disposing the substrate holder 11 in the plating tank 10, necessary pre-processing or the like may be performed.

When the substrate holder 11 is disposed in the plating tank 10, the plating tank 10 is divided by the substrate holder 11 and the substrate W (S106). More specifically, the plating tank 10 is divided into the first portion 10a and the second portion 10b by the sealing member 116 of the substrate holder 11. For example, when the sealing member 116 is formed of the bag body 117 shown in FIG. 5A to FIG. 5C, the guide concave portion 17 of the plating tank 10 is sealed by supplying a gas such as air into the bag body 117 to cause the bag body 117 to inflate. For example, when the sealing member 116 is formed of the bag body 117 and the wedge member 119 shown in FIG. 9A to FIG. 9D, the rotating shaft 118 is made to rotate to seal the guide concave portion 17 of the plating tank 10. Furthermore, as described above, a contact sensor may be provided in the guide concave portion 17 to confirm, using the contact sensor, whether or not sealing is in progress appropriately.

Next, the plating liquid is supplied to the divided parts of plating tank 10 (S108). More specifically, the plating liquid is supplied to the first portion 10a and the second portion 10b of the plating tank 10 respectively. The plating liquid to be supplied may differ depending on the plating process applied to the substrate W. If the same plating process is applied to the front surface and the back surface of the substrate W, plating liquids of the same type are supplied to the first portion 10a and the second portion 10b of the plating tank 10. If different plating processes are applied to the front surface and the back surface of the substrate W, plating liquids of different types (e.g., plating liquids containing various components varying in concentration or temperature) may be supplied to the first portion 10a and the second portion 10b of the plating tank 10. As described above, since the first portion 10a and the second portion 10b of the plating tank 10 are fluidically separated by the substrate holder 11 and the substrate W, the plating liquids are never mixed in the first portion 10a and the second portion 10b.

After the plating liquid is supplied into the plating tank 10, currents are supplied to the front surface and the back surface of the substrate to start a plating process (S110). Magnitude of currents to be supplied to the front surface and the back surface of the substrate, the size of the opening 33 of the anode mask 32, the size of the opening of the intermediate mask, the temperature of the plating liquid or the like are adjusted according to a predetermined recipe. Note that during the plating process, the plating liquids may be made to circulate using the plating liquid circulation mechanism described together with FIG. 6A.

When the plating process on the front surface and the back surface of the substrate W is completed according to the predetermined recipe, the plating process is ended (S112). In order to prevent the plating liquid of the first portion 10a and the plating liquid of the second portion 10b of the plating tank 10 from mixing together, the respective plating liquids may be evacuated to the first buffer tank 250a and the second buffer tank 250b before raising the substrate holder 11 from the plating tank 10 (see FIG. 6A). After the plating liquids are evacuated to the first buffer tank 250a and the second buffer tank 250b, the sealing between the substrate holder 11 and the guide concave portion 17 of the plating tank 10 is opened. More specifically, when the sealing member 116 is formed of the bag body 117 shown in FIG. 5A to FIG. 5C, the gas such as air is released from the bag body 117 and the sealing between the bag body 117 and the guide concave portion 17 of the plating tank 10 is opened. For example, when the sealing member 116 is formed of the bag body 117 or the wedge member 119 shown in FIG. 9A to FIG. 9D, the rotating shaft 118 is rotated to open the sealing between the substrate holder 11 and the guide concave portion 17 of the plating tank 10. After opening the sealing, the substrate holder 11 is raised from the plating tank 10, the substrate W is cleaned, various processes such as drying are applied and the plated. substrate W is then returned to a predetermined place. In this way, a plating process can be performed on the front surface and the back surface of one substrate W at a time.

The above-described plating method can be automatically performed by controlling the plating apparatus through the control section 103. According to the embodiment, the control section 103 can be constructed of a common computer or a special purpose computer provided with an input/output apparatus, a CPU, a storage apparatus, a display apparatus or the like. The control section 103 stores a program to automatically control overall operation of the plating apparatus according to a user-selected or inputted processing recipe. The program to automatically control overall operation of the plating apparatus may be stored in a non-volatile storage medium or enabled to be transmitted to a target computer via a network such as the Internet.

A plating apparatus using a substrate holder has been described in the foregoing embodiment where a substrate is disposed in a longitudinal direction with respect to a plating tank and soaked in a plating liquid, but the present invention is not limited to such an embodiment, and a plating apparatus using a substrate holder where a substrate is disposed in a horizontal direction with respect to the plating tank (referred to as a “cup-type substrate holder”) may also be adopted. When plating is performed using this apparatus, the apparatus is configured to perform a plating process such that after a plating process ends, the plating liquid positioned above the substrate is drained first, followed by draining of the plating liquid positioned below the substrate. When the substrate is large in size, if the substrate is soaked vertically with respect to the plating liquid, a temperature gradient may be generated above or below the substrate. Therefore, if plating is performed using a plating apparatus where the substrate is disposed horizontally, it is possible to prevent generation of a temperature gradient within the substrate surface, and so it is possible to more reliably secure in-plane uniformity in the plating film thickness. Alternatively, a plating process may be performed using a membrane that allows transmission of only a specific ion component in the plating liquid.

Although the embodiments of the present invention have been described based on several examples, the above-described embodiments are intended to facilitate an understanding of the present invention, not to limit the present invention. It goes without saying that the present invention can be modified or improved without departing from the spirit and scope of the present invention and the present invention includes equivalents thereof. Any combination or omission of the components described in the scope of claims and the specification is possible within a range in which at least some of the aforementioned problems can be solved or within a range in which at least some of effects can be exerted.

### REFERENCE SIGNS LIST

10 . . . Plating tank
10a . . . First portion
10b . . . Second portion
11 . . . Substrate holder
14a . . . Electric contact
14b . . . Electric contact
15a . . . Gas supply contact
15b . . . Gas supply contact
16 . . . External tank
16a . . . First portion
16b . . . Second portion
18a . . . Partition member
18b . . . Partition member
17 . . . Guide concave portion (holder holding section
103 . . . Control section
116 . . . Sealing member
117 . . . Bag body
118 . . . Rotating shaft
119 . . . Wedge member
202a . . . First circulation line
202b . . . Second circulation line
206a . . . First pump
206b . . . Second pump
208a . . . First temperature control apparatus
208b . . . Second temperature control apparatus
210a . . . First filter
210b . . . Second filter
250a . . . First buffer tank
250b . . . Second buffer tank
252a . . . First buffer line
252b . . . Second buffer line
W . . . Substrate

What is claimed is:

1. A substrate holder for holding a substrate which is a plating target during a plating process, the substrate holder comprising:
a body part for holding the substrate, the body part defining a first opening and a second opening, wherein
the body part is configured such that when the body part holds the substrate, a plated region on a front surface of the substrate is exposed through the first opening and a plated region on a back surface of the substrate is exposed through the second opening, and
at least a part of a peripheral portion of the body part comprises a sealing part that protrudes from the peripheral portion.

2. The substrate holder according to claim 1, further comprising:
a first power supply mechanism for supplying a current to the front surface of the substrate; and
a second power supply mechanism for supplying a current to the back surface of the substrate.

3. The substrate holder according to claim 1, wherein the sealing part comprises a bag body configured to inflate by introducing a gas thereinto.

4. The substrate holder according to claim 1, wherein the sealing part comprises a rotatable wedge member.

5. The substrate holder according to claim 1, wherein the sealing part comprises at least one elastic member selected from a group of (1) a coated elastic member containing paraxylylene, (2) an elastic member containing polyvinylidene fluoride (PVDF), (3) an elastic member containing polytetrafluoroethylene (PTFE), (4) an elastic member containing a copolymer including at least one of polyvinylidene fluoride (PVDF) and polytetrafluoroethylene (PTFE), and (5) an elastic member made of two-liquid fluorine rubber-based sealing member.

6. The substrate holder according to claim 1, wherein the sealing part is provided at a position corresponding to a holder holding section of a plating tank when the substrate holder is disposed in the plating tank.

7. A plating apparatus comprising:
a plating tank for containing a plating liquid; and
a substrate holder for holding a substrate which is a plating target; wherein
the substrate holder comprises:
a body part for holding the substrate, the body part comprising a first opening and a second opening, the body part is configured such that when the body part holds the substrate, a plated region on a front surface of the substrate is exposed through the first opening and a plated region on a back surface of the substrate is exposed through the second opening,
a sealing part protruding from a peripheral portion of the body part is included in at least part of the peripheral portion,
the plating tank comprises a holder holding section that receives the sealing part of the substrate holder, and
when the sealing part is received by the holder holding section of the plating tank, the substrate and the substrate holder divide the plating tank into a first portion and a second portion.

8. The plating apparatus according to claim 7, wherein the substrate holder comprises:
a first power supply mechanism for supplying a current to the front surface of the substrate; and
a second power supply mechanism for supplying a current to the back surface of the substrate.

9. The plating apparatus according to claim 7, wherein the sealing part comprises a bag body configured to inflate by introducing a gas thereinto.

10. The plating apparatus according to claim 7, wherein the sealing part comprises a rotatable wedge member.

11. The plating apparatus according to claim 7, wherein the holder holding section comprises a contact sensor.

12. The plating apparatus according to claim 7, further comprising an external tank that receives a plating liquid overflowing from the plating tank.

13. The plating apparatus according to claim 12, wherein the external tank comprises a removable partition member for dividing the external tank into a first portion and a second portion.

14. The plating apparatus according to claim 13, wherein the plating liquid overflowing from the first portion of the plating tank is received by the first portion of the external tank and the plating liquid overflowing from the second portion of the plating tank is received by the second portion of the external tank.

15. The plating apparatus according to claim 14, further comprising:
a first circulation mechanism for causing the plating liquid to circulate from the first portion of the external tank to the first portion of the plating tank; and
a second circulation mechanism for causing the plating liquid to circulate from the second portion of the external tank to the second portion of the plating tank.

16. The plating apparatus according to claim 7, further comprising:
a first buffer tank for temporarily storing the plating liquid at the first portion of the plating tank; and
a second buffer tank for temporarily storing the plating liquid at the second portion of the plating tank.

17. A plating method comprising:
a step of holding a substrate in a substrate holder such that a plating target region of a front surface and a plating target region of a back surface of the substrate are exposed;
a step of disposing the substrate holder holding the substrate in a plating tank;
a step of dividing the plating tank into fluidically separated first and second portions by the substrate holder holding the substrate;
a step of supplying a first plating liquid to a first portion of the plating tank;
a step of supplying a second plating liquid to a second portion of the plating tank;
a step of applying a plating process to a plating target region on the front surface of the substrate using the first plating liquid; and
a step of applying a plating process to a plating target region on the back surface of the substrate using the second plating liquid.

18. The plating method according to claim 17, wherein the step of plating the front surface of the substrate and the step of plating the back surface of the substrate are controlled independently of each other.

19. The plating method according to claim 18, wherein the first plating liquid and the second plating liquid are controlled independently of each other.

20. The plating method according to claim 17, wherein the first plating liquid and the second plating liquid are different plating liquids.
